(19) United States
(12) Patent Application Publication
(10) Pub. No.: US 2006/0113619 A1
(43) Pub. Date: Jun. 1, 2006

(54) Magnetic random access memory with reference magnetic resistance and reading method thereof

(76) Inventors: Chien-Chung Hung, Hsinchu (TW); Yung-Hsiang Chen, Hsinchu (TW); Ming-Jer Kao, Hsinchu (TW); Kuo-Lung Chen, Hsinchu (TW); Lien-Chang Wang, Hsinchu (TW); Yung-Hung Wang, Hsinchu (TW)

Correspondence Address: RABIN & Berdo, PC, 1101 14TH STREET, NW, SUITE 500, WASHINGTON, DC, 20005, US

(21) Appl. No.: 11/224,082

(22) Filed: Sep. 13, 2005

(30) Foreign Application Priority Data
Dec. 1, 2004 (TW) 093137071

(51) Int. Cl. H01L 43/00

(52) U.S. Cl. 257/421

(57) ABSTRACT

A magnetic random access memory having reference magnetic resistance is provided. The memory includes at least one magnetic memory cell having an antiferromagnet layer, a pinned layer formed thereon, a tunnel barrier layer formed thereon, and a free layer formed thereon. The pinned layer and free layer are arranged orthogonally to form a reference magnetic resistance state. Through the provided MRAM structure, the access accuracy is greatly increased and the access speed is accelerated.

This application claims the benefit of Taiwan Patent Application No. 93137071, filed on Dec. 1, 2004, which is hereby incorporated by reference for all purposes as if fully set forth herein.

### BACKGROUND OF THE INVENTION

1. Field of Invention

The invention relates to a magnetic random access memory and, in particular, to a magnetic random access memory that accesses data by referring to the states of adjacent bits or near bits.

2. Related Art

The magnetic random access memory (MRAM) is a type of nonvolatile memory. It utilizes magnetic resistance properties to record information and has the advantages of non-volatility, high density, high read/write speed, and anti-radiation. When writing data, a common method is to use the intersection of the induced magnetic fields of two circuit lines, the bit line and the write word line to select a cell. The resistance is changed by changing the magnetization of the magnetic material layer. When the MRAM reads recorded data, a current is supplied to the selected magnetic memory cell to read its resistance, thereby determining the corresponding digital value.

The magnetic memory cell between the bit line and the write word line is a stacked structure of a multi-layered metal material. It consists of a stack with a soft ferromagnetic layer, a tunnel barrier layer, a hard ferromagnetic layer, an antiferromagnet layer, and a nonmagnetic conducting layer. Controlling the magnetizations of the two ferromagnetic layers to be parallel or anti-parallel determines the memory state to be “0” or “1.”

The magnetoresistance in the magnetic memory cell may not distribute uniformly because of the manufacturing process. To solve this problem, a reference bit line is provided in addition to a specific quantity of bit lines, for example 32 or 64. Therefore, the stored data may be determined by referring to the reference bit line when accessing the data stored in the memory cell. However, this approach may result in data error, and increase the error rate.

U.S. Pat. No. 6,654,278 discloses a method of self-reference sensing to address this problem. The initial states of the free layer and pinned layer are arranged orthogonally. Assisted magnetic field in two different directions is introduced when accessing data. Thus, the logic states of the memory are determined through positive or negative slope for the magneto-resistance variance. However, the operation may be very complicated and lead to slow access speed.

Furthermore, the signal delivered to the sensing circuit is a single-ended signal in the self-reference sensing mode of the prior art such that specific circuitry is needed to detect the slope variance of the magnetic resistance. Thus, the operation speed is slow.

Therefore, there is a need to develop another MRAM architecture to solve the problems of data accuracy and accessing speed.

### SUMMARY OF THE INVENTION

In view of the foregoing, an MRAM is provided to solve the existing problems according to the embodiments illustrated in the following.

According to the embodiment of the invention, the MRAM may increase the accessed data accuracy.

According to the embodiment of the invention, the MRAM may increase data accessing speed.

According to the embodiment of the invention, the MRAM may increase cell reliability.

According to the embodiment of the invention, the MRAM comprises at least one magnetic memory cell that comprises an antiferromagnet layer, a pinned layer provided conjuction with the antiferromagnet layer, a tunnel barrier layer provided conjunction with the pinned layer, and a free layer provided conjunction with the tunnel barrier layer. The magnetic vectors of the pinned layer and the free layer are arranged orthogonally to form a reference magnetic resistance state.

According to the embodiment of the invention, the MRAM comprises a plurality of magnetic memory cells, each comprising an antiferromagnet layer, a pinned layer provided conjunction with the antiferromagnet layer, a tunnel barrier layer provided conjunction with the pinned layer, and a free layer provided conjunction with the tunnel barrier layer. The magnetic vectors of the pinned layer and the free layer are arranged orthogonally to form a reference magnetic resistance state. The MRAM also comprises a plurality of write word lines for selecting the memory cell to be written; a plurality of read word lines for selecting the memory cell to be read; a plurality of transistors provided on the read word lines corresponding each of the magnetic memory cell as switches for the memory cell to be read; a plurality of first bit lines for providing a current to determine the data stored in the magnetic memory cell selected by the read word line; a plurality of second bit lines for providing a current to write data into the magnetic memory cell selected by the write word line and to rotate the magnetic vector of the pinned layer of the magnetic memory cell selected by the read word line; and a plurality of sense amplifiers connected to the first bit lines to amplify the first current signal of the magnetic memory cell selected by the read word line and the second current signal of a magnetic memory cell adjacent or close to the selected magnetic memory cell, then output the amplified current signals. The second current signal is a reference signal as compared to the first current signal.

According to the object and principle of the invention, the MRAM may select an adjacent or close memory cell as an reference cell. Therefore, compared wit the technology in the prior art, the memory cells in a specific area do not need to use the same reference cell and do not need to arrange additional reference cells.

According to the principle of the invention, the MRAM has the advantage of increasing the data reorganization rate.

According to the principle of the invention, the MRAM may reduce the improper affection when reading data caused by lack of uniformity in manufacturing.

According to the principle of the invention, the MRAM has equalization chrematistics. Therefore, the operation time for equalization is reduced and the access speed is increased.

According to the principle of the invention, the write word lines and the read word lines are separate. The capacitance loading is reduced when writing data.

In the following description, for purposes of explanation, numerous specific details are set forth in order to provide a thorough understanding of the invention. It will be apparent, however, to one skilled in the art that the invention can be practiced without these specific details. In other instances, structures and devices are shown in block diagram form in order to avoid obscuring the invention.

### BRIEF DESCRIPTION OF THE DRAWINGS

The above and other objects, features and advantages of the invention will be more clearly understood from the following detailed description when taken in conjunction with the accompanying drawings, in which:

FIG. 1 illustrates the MRAM of the invention;

FIG. 2 illustrates another embodiment of the MRAM of the invention;

FIG. 3 illustrates the arrangement of the MRAM of the invention;

FIG. 4 illustrates the circuitry of the MRAM of the invention in general; and

FIG. 5 illustrates the circuitry of the MRAM of the invention applied in TOGGLE mode.

### DETAILED DESCRIPTION OF THE INVENTION

Reference will now be made in greater detail to a preferred embodiment of the invention, an example of which is illustrated in the accompanying drawings. Wherever possible, the same reference numerals will be used throughout the drawings and the description to refer to the same or like parts. Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

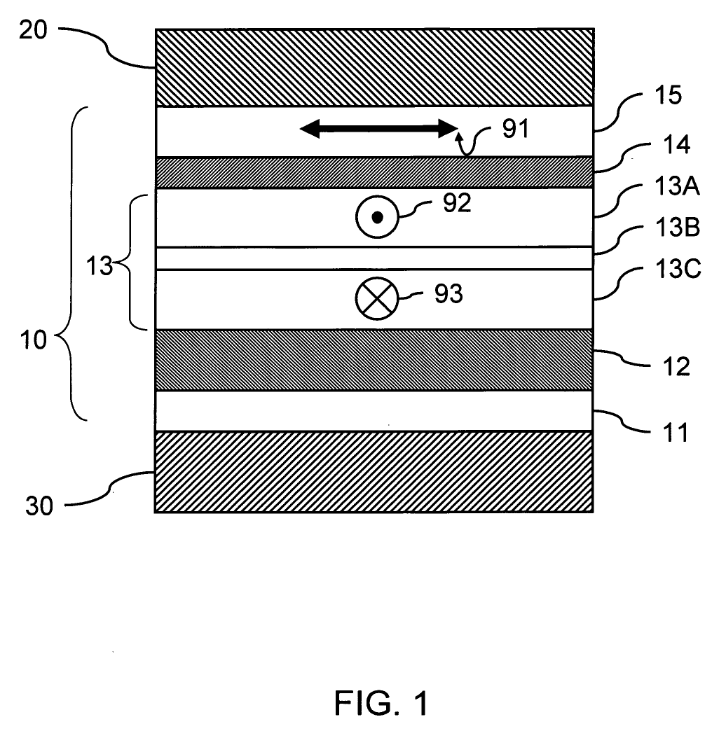

FIG. 1 shows a simplified cross-sectional view of an MRAM. The drawing also shows a single MRAM (or memory cell). The actual MRAM array can be composed of several MRAMs, as shown in FIG. 1.

The magnetic random access memory includes a magnetic memory cell 10, an upper electrode 20 and a lower electrode 30. The magnetic memory cell 10 is composed of multiple magnetic layers, or an MTJ. The upper electrode 20 and the lower electrode 30 are formed by conductive material for current flow. In the drawing, the upper electrode 20 is provided on top of the magnetic memory cell 10, while the lower electrode 30 is provided on the bottom of the magnetic memory cell 10. As known to those skilled in the art, the upper electrode 20 and the lower electrode 30 may respectively connect with a transistor and bit line for accessing and writing data.

In the drawing, the magnetic memory cell 10 has a seven-layer structure, which includes a buffer layer 11, an antiferromagnet layer 12, an upper pinned layer 13A or named reference layer, an intermediate layer 13B, a lower pinned layer 13C, a tunnel barrier layer 14, and a free layer 15. For example, the buffer layer 11 may be formed by NiFe or NiFeCr.

The antiferromagnet layer 12 may be formed by PtMn or MnIr. The pinned layer 13 may adopt at least one ferromagnet layer or an artificial antiferromagnet layer with a three-layer structure. CoFe/Ru/CoFe or CoFeB/Ru/CoFeB may be adopted as the material for the artificial antiferromagnet layer. The tunnel barrier layer 14 may employ AlOx or MgO, while the free layer may adopt at least one ferromagnet layer or an artificial antiferromagnet layer with a three-layer structure. NiFe/CoFe or CoFeB may be used as the material for the ferromagnet layer, while CoFe/Ru/CoFe, NiFe/Ru/NiFe or CoFeB/Ru/CoFeB may be adopted as the material for the artificial antiferromagnet layer. The listed materials are used for illustration only. As known to those skilled in the art, other magnetic materials that achieve the same technical result may be also employed. The magnetic vectors 92 and 93 of the pinned layer 13 and the magnetic vector 91 of the free layer 15 are arranged orthogonally such that an intermediate state of magnetic resistance is formed. The orthogonally arranged pinned layer and free layer are manufactured by arranging the easy axis of the magnetic memory cell to be vertical through photo masking with a film coating external field and subsequent annealing field.

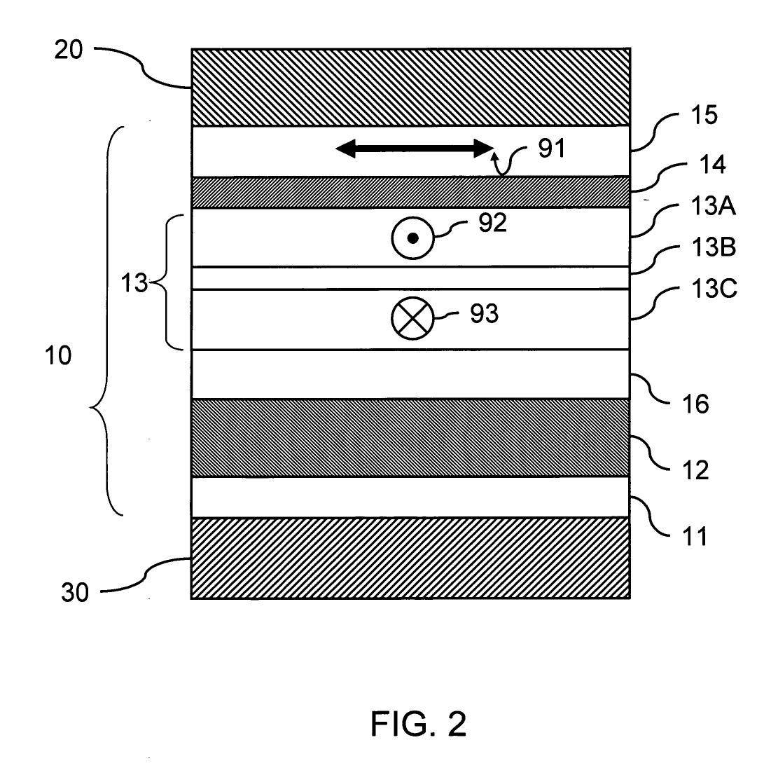

An additional current is provided to agitate the magnetic filed of the pinned layer 13 when reading the data stored in the magnetic random access memory of the invention. Thus, the exchange bias between the antiferromagnet layer 12 and the pinned layer 13 may be lowered appropriately to agitate the magnetic filed of the pinned layer 13. In one embodiment, a thin metal layer 16 is provided between the antiferromagnet layer 12 and the pinned layer 13, as shown in FIG. 2, to reduce the exchange bias between the antiferromagnet layer 12 and the pinned layer 13. The depth of the metal layer 16 is substantially less than 10 A. In another embodiment for employing the artificial antiferromagnet layer as the pinned layer 13, the depth of the intermediate layer 13 (ex. Ru) between the upper pinned layer and the lower pinned layer is adjusted to reduce the RKKY (Ruderman-Kittel-Kasuya-Yosida) coupling capability.

The arrangement of the pinned layer 13 and the free layer 15 in the magnetic memory cell 10 is orthogonal without an external magnetic filed, and is defined as an intermediate reference. It is well known to those skilled in the related art that a Cross Selection mode or Toggling Mode may be employed as the writing mechanism for the free layer 15 of the magnetic memory cell 10.

According to the principle of the invention, an additional current is provided to agitate the magnetic field of the pinned layer 13 when accessing data. For different stored data, the magnetic resistance is varied from the intermediate reference state to a parallel state or anti-parallel state. Meanwhile, the memory cell in the near bit line and the same word line is selected and not provided with magnetic disturbance such that an intermediate reference signal is provided as compared with the selected memory cell.

The MRAM stores data through the pinned layer 13, the tunnel barrier layer 14, and the free layer 15. The stored data is determined by the parallel magnetic vectors or the anti parallel magnetic vectors of the pinned layer 13 and the free layer 15 under the magnetic disturbance.

When the two magnetic vectors are parallel, the magnetic resistance of the MRAM is lowest, which is defined as “0”. Therefore, a larger current flows through the MRAM when applying a bias voltage. When the two magnetic vectors are anti parallel, the magnetic resistance of the MRAM is highest, which is defined as “1”. Therefore, a smaller current flows through the MRAM when applying a bias voltage. It is known to those skilled in the art that this definition is only for illustration and explanation, and any other definition may be implemented.

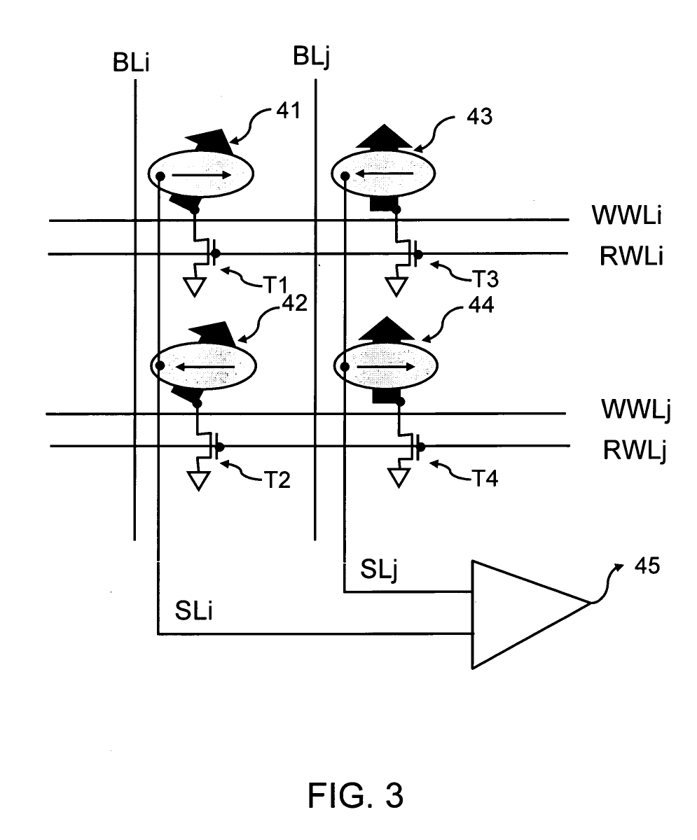

Refer to FIG. 3, which illustrates the arrangement of the magnetic random access memory of the invention.

The magnetic memory cells in FIG. 3 are fabricated from the above composition. As illustrated in the figure, each magnetic memory cell 41˜44 is connected to the write word line WWLi, WWLj and second bit lines BLi, BLj respectively. For example, the magnetic memory cell 41 connects to the write word line WWLi and the second bit line BLi. The write word lines WWLi, WWLj are used to select the magnetic cell that is to be written upon. The first bit lines SLi, SLj are used to provide sensing current to determine the memory state of the memory cell. The second bit lines BLi, BLj are used to supply write current for writing data of the memory cell, and provide an additional current when reading data such that the magnetic vector in the pinned layer of the selected memory cell rotates. Furthermore, the first bit lines SLi, SLj are connected to an amplifier 45 to amplify and output the read current. The plurality of read word lines RWLi, RWLj is used to select the magnetic memory cell that is to be accessed. The transistors T1˜T4 are used as switches for reading data in the memory cell.

The operation of the invention is now illustrated in detail. The initial states of the pinned layers and the free layers of the magnetic memory cell 41˜44 are orthogonal, i.e. the moments are perpendicular to each other. The memory cells 43 and 44 in the figure are at the initial state, i.e. reference magnetic resistance. The magnetic vector of the pinned layer and the free layer are orthogonal. The magnetic resistance changes from the intermediate state to the parallel state (low magnetic resistance) or anti parallel state (high magnetic resistance) according to the data stored in the memory cell when reading the data. For example, when the magnetic memory cell 41 is selected, an assisted magnetic field that does not change the stored data is provided by the bit line BLi on the magnetic memory cell 41. The stored data is delivered through the first bit line SLi, which is defined as a first current signal. Meanwhile, a magnetic memory cell 43 is selected in the adjacent second bit line BLj and in the same read word line where the magnetic memory cell 43 is arranged. The second bit line BLj does not provide the assisted field to the magnetic memory cell 43, and the first bit line SLj delivers a second current signal. Hence, the second current signal is used as reference as compared to the first current signal. The data reorganization rate is thus increased due to the balanced RC loading of adjacent memory cells.

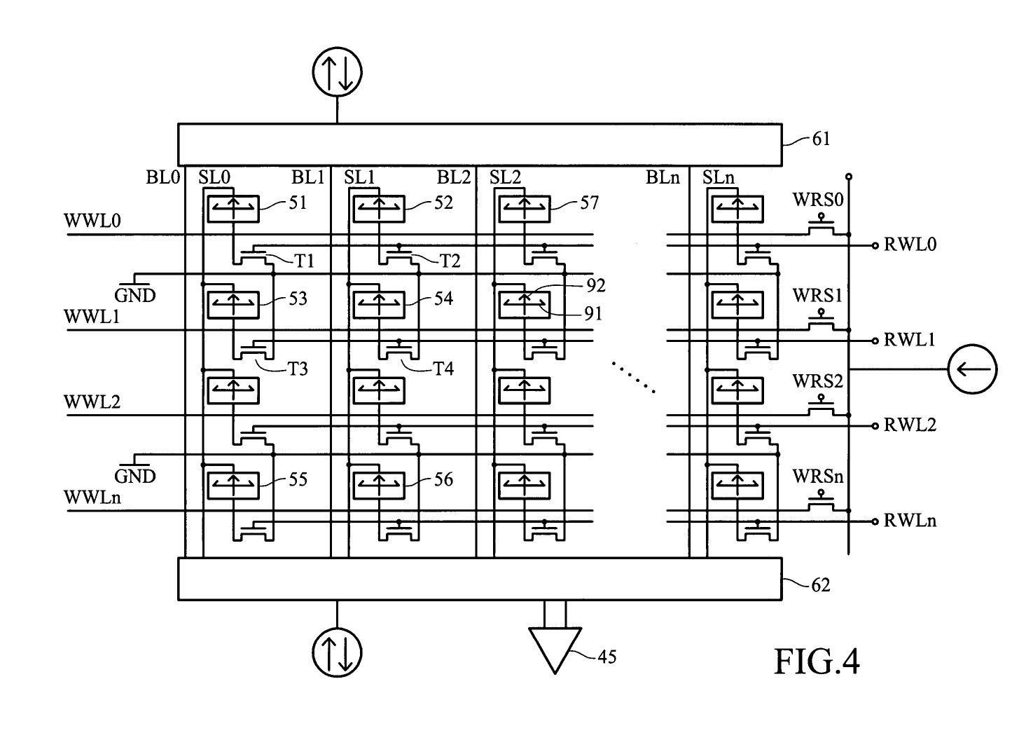

FIG. 4 illustrates the circuitry of the MRAM with reference magnetic resistance of the invention, which is applied for the general memory structure.

FIG. 4 shows a magnetic random access memory array composed of a plurality of magnetic memory cells 51, 52, 53, 54, 55, 56 . . . Similarly, the magnetic vectors 91 and 92 of the pinned layers and the free layers of the magnetic memory cells 51, 52, 53, 54, 55, 56 are arranged orthogonally. The transistors T1, T2, T3, and T4 control the selection of the memory cells. The transistors on the same row are controlled by read word lines RWL0˜RWLn. For example, the transistors T1, T2 are controlled by the read word line RWL0. Each memory cell connects to the write word lines WWL0˜WWLn and the second bit lines BL1˜BLn respectively. Each write word line is controlled by the transistors WRS0˜WRSn such that the write word lines may be selected by control circuits through the transistors WRS0˜WRSn. The first bit lines SL0˜SLn amplify the accessed current signal by the second multiplexer 62 and a amplifier 45. The second bit lines BL1˜BLn connect to the first multiplexer 61 and the second multiplexer 62 for providing write-in current to write the data into the magnetic memory cell. The second bit lines BL1˜BLn also provide an additional current to agitate the pinned layer of the selected magnetic memory cell.

In the embodiment, the provided write-in current may drive the magnetic memory cells bi-directionally through the second bit lines BL1˜BLn. In the embodiment, the magnetic memory cell in the same word line bit but the different bit line is selected as reference. An adjacent or close magnetic memory cell may be selected. The bit lines may be but don't have to be adjacent. For example, when accessing the data stored in the magnetic memory cell 51, the magnetic memory cell 52 or 57 is selected as reference, while the magnetic memory cell 55 is selected as reference when accessing the data stored in the magnetic memory cell 56.

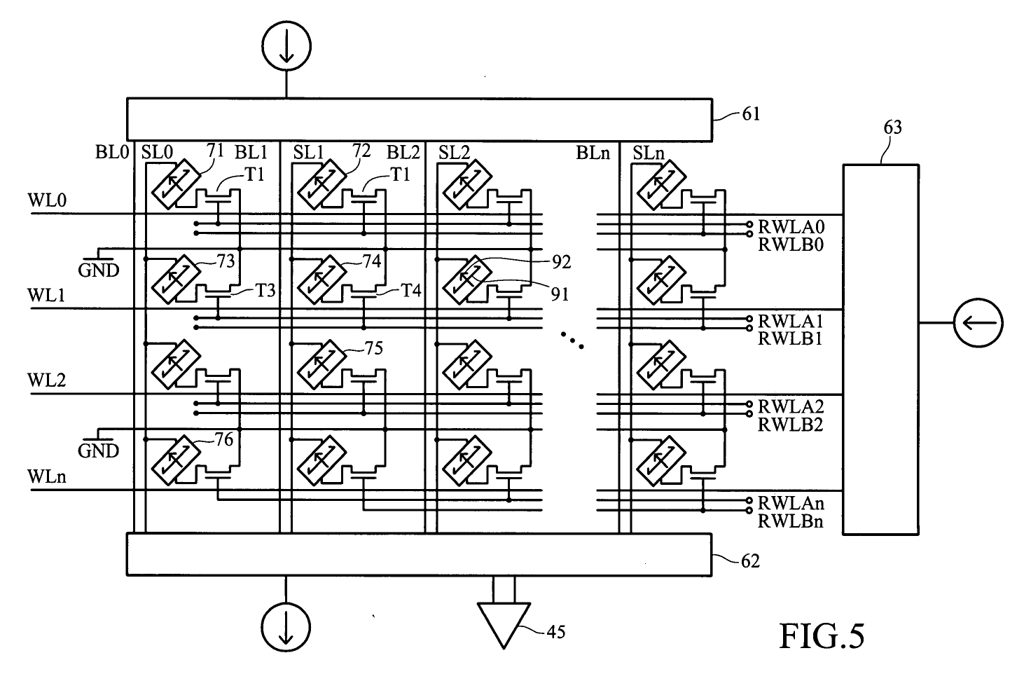

FIG. 5 illustrates the circuitry of the MRAM with reference magnetic resistance of the invention, which is applied for the Toggle mode memory structure.

FIG. 5 shows a magnetic random access memory array composed of a plurality of magnetic memory cells 71, 72, 73, 74, 75, 76 . . . Similarly, the magnetic vectors 91 and 92 of the pinned layers and the free layers of the magnetic memory cells 71, 72, 73, 74, 75, 76 are arranged orthogonally. The transistors T1, T2, T3, and T4 control the selection of the memory cells. The transistors on the same row are controlled by first read word lines and second read word lines. For example, the transistor T1 is controlled by the first read word line RWLA0, while the transistor T2 is controlled by the second read word line RWLA1. Each memory cell connects to the word lines WL0˜WLn and the second bit lines BL1˜BLn respectively. Each word line is controlled by a third multiplexer 63 such that the word lines may be selected by control circuits through the third multiplexer 63 for providing write-in current to write the data. The word lines WL0˜WLn also provide an additional current to agitate the pinned layer of the selected magnetic memory cell. The first bit lines SL0˜SLn connect to an amplifier 45 through a second multiplixier 62 to amplify and output the accessed current. The second bit lines BL1˜BLn connect to the first multiplexer 61 and the second multiplexer 62 for providing write-in current to write the data into the magnetic memory cell. The second bit lines BL1˜BLn also provide an additional current to agitate the pinned layer of the selected magnetic memory cell.

In the embodiment, the provided write-in current may drive the magnetic memory cells unidirectionally or bidirectionally through the second bit lines BL1˜BLn and the word lines WL1˜WLn. In the embodiment, the selected magnetic memory cells are diagonally arranged. I.e., the magnetic memory cells in the different word lines and bit lines are selected as reference. The different word lines and bit lines are adjacent or close to each other. For example, when accessing the data stored in the magnetic memory cell 71, the magnetic memory cell 74 is selected as reference, while the magnetic memory cell 75 is selected as reference when accessing the data stored in the magnetic memory cell 76.

The magnetic random access memory with reference magnetic resistance of the invention arranges the magnetic vectors of the pinned layer and the free layer orthogonally. For the read mechanism, the selected memory cell is disturbed by the assisted magnetic field that does not change the stored data, thereby providing a first data signal for the amplifier. Besides, an adjacent or a close memory cell is selected as reference, thereby providing a second data signal for the amplifier. Therefore, the accuracy and access speed is increased.

The embodiments in the figures are only illustrative and exemplary, and are not intended to limit the invention. The advantages and effects of the magnetic random access memory with reference magnetic resistance of the invention are given as follows.

The magnetic random access memory with reference magnetic resistance of the invention arranges the magnetic vectors of the pinned layer and the free layer orthogonally. The selected memory cell is disturbed by the assisted magnetic field that does not change the stored data, thereby providing a data signal for the sensing circuit when reading data. Besides, the adjacent close memory cell is used as a reference unit to provide the reference signal for the sensing circuit.

A differential amplifier that has faster operation speed is employed for the data reading operation. The reference signal is obtained from the selected memory cell to determine the data state correctly.

According to the object and principle of the invention, the magnetic random access memory may increase the accuracy when reading data, and may access data promptly.

According to the object and principle of the invention, the magnetic random access memory does not increase the memory areas necessary for the reference signals.

According to the object and principle of the invention, two signals are provided to the sensing circuits at the same operation period. In the reading operation, the equalization of the bit line data is accomplished. Therefore, the operation of the memory is prompt and accurate.

According to the object and principle of the invention, the two signals are generated at the adjacent or close bits; therefore, time delay (RC delay) for delivering the signals to the sensing amplifier is very balanced. Thus, the efficiency of the memory is increased.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A magnetic random access memory with reference magnetic resistance, comprising:
at least one magnetic memory cell which comprises an antiferromagnet layer, a pinned layer provided conjunction with the antiferromagnet layer, a tunnel barrier layer provided conjunction with the pinned layer, and a free layer provided conjunction with the tunnel barrier layer;
wherein the magnetic vectors of the pinned layer and the free layer are arranged orthogonally to form reference magnetic resistance state.

2. The MRAM of claim 1, wherein the orthogonally arranged pinned layer and free layer is manufactured by arranging the easy axis of the magnetic memory cell to be vertical through photo mask with an film coating external field and subsequent annealing field.

3. The MRAM of claim 1, wherein a metal layer is formed between the antiferromagnet layer and the pinned layer to reduce the exchange bias therebetween.

4. The MRAM of claim 3, wherein the depth of the metal layer is less than 10 A.

5. The MRAM of claim 1, wherein the pinned layer comprises at least one ferromagnet layer.

6. The MRAM of claim 1, wherein the pinned layer comprises a lower pinned layer, a intermediate layer formed on the lower pinned layer, and a upper pinned layer formed on the intermediate layer.

7. The MRAM of claim 1, wherein the pinned layer comprises a plurality of artificial antiferromagnet layers.

8. The MRAM of claim 1, wherein the depth of the intermediate layer of the artificial antiferromagnet layer is adjusted to reduce the RKKY (Ruderman-Kittel-Kasuya-Yosida) coupling capability thereof.

9. The MRAM of claim 1, wherein the free layer comprises at least one ferromagnetic layer.

10. The MRAM of claim 1, wherein the free layer comprises a plurality of artificial antiferromagnet free layers.

11. A magnetic random access memory with reference magnetic resistance, comprising:
a plurality of magnetic memory cells, each which comprises an antiferromagnet layer, a pinned layer provided conjunction with the antiferromagnet layer, a tunnel barrier layer provided conjunction with the pinned layer, and a free layer provided conjunction with the tunnel barrier layer, wherein the magnetic vectors of the pinned layer and the free layer are arranged orthogonally to form reference magnetic resistance state;
a plurality of write word lines for selecting the memory cell to be written;
a plurality of read word lines for selecting the memory cell to be read;
a plurality of transistors provided on the read word lines corresponding each of the magnetic memory cell as switches for the memory cell to be read;
a plurality of first bit lines for providing a current to determine the data stored in the magnetic memory cell selected by the read word line;
a plurality of second bit lines for providing a current to write data into the magnetic memory cell selected by the write word line, and providing a current to rotate the magnetic vector of the pinned layer of the magnetic memory cell selected by the read word line; and
a plurality of amplifiers connected to the first bit lines respectively to amplify a first current signal of the magnetic memory cell selected by the read word line and a second current signal of a magnetic memory cell adjacent or close to the selected magnetic memory cell, then output the amplified current signals, wherein the second current signal is a reference signal as compared to the first current signal.

12. The MRAM of claim 11, further comprises a first multiplexer connected to the second bit line.

13. The MRAM of claim 11, further comprises a second multiplexer connected to the first bit line and the second bit line.

14. The MRAM of claim 11, further comprises a third multiplexer connected to each of the word line.

15. The MRAM of claim 11, wherein the orthogonally arranged pinned layer and free layer is manufactured by arranging the easy axis of the magnetic memory cell to be vertical through photo mask with an film coating external field and subsequent annealing field.

16. The MRAM of claim 11, wherein a metal layer is formed between the antiferromagnet layer and the pinned layer to reduce the exchange bias therebetween.

17. The MRAM of claim 16, wherein the depth of the metal layer is less than 10 A.

18. The MRAM of claim 11, wherein the pinned layer comprises at least one ferromagnet layer.

19. The MRAM of claim 11, wherein the pinned layer comprises a plurality of artificial antiferromagnet layers.

20. The MRAM of claim 19, wherein the depth of the intermediate layer of the artificial antiferromagnet layer is adjusted to reduce the RKKY (Ruderman-Kittel-Kasuya-Yosida) coupling capability thereof.

21. The MRAM of claim 11, wherein the free layer comprises at least one ferromagnetic layer.

22. The MRAM of claim 11, wherein the free layer comprises a plurality of artificial antiferromagnet free layers.

23. A reading method of magnetic random access memory with reference magnetic resistance, comprising:
selecting magnetic memory cell by a read word line;
selecting a magnetic memory cell adjacent or close to the magnetic memory cell selected by the read word line as reference;
providing a current by a second bit line to rotate the pinned layer of the magnetic memory cell selected by the read word line;
providing a current by a first bit line to determine the data stored in the magnetic memory cell selected by the read word line;and
amplifying and outputting a first current signal of the magnetic memory cell selected by the read word line and a second current signal of the magnetic memory cell adjacent or close to the magnetic memory cell selected by the read word line.

24. The reading method of claim 23, wherein the adjacent magnetic memory cell and the magnetic memory cell selected by the read word line are in the same word line but different bit lines.

25. The reading method of claim 24, wherein the different bit lines are adjacent to each other.

26. The reading method of claim 24, wherein the different bit lines are not adjacent to each other.

27. The reading method of claim 23, wherein the adjacent magnetic memory cell and the magnetic memory cell selected by the read word line are in different word lines and different bit lines, wherein the adjacent magnetic memory cell and the magnetic memory cell selected by the read word line are diagonal to each other.

28. The reading method of claim 27, wherein the different word lines are adjacent or closes to each other, and different bit lines are adjacent or closes to each other.
